(19) United States
(12) Patent Application Publication
(10) Pub. No.: US 2025/0254895 A1
(43) Pub. Date: Aug. 7, 2025

(54) THIN FILM RESISTOR STRUCTURE AND MANUFACTURING METHOD OF THIN FILM RESISTOR STRUCTURE

(71) Applicant: Silergy Semiconductor Technology (Hangzhou) LTD, Hangzhou (CN)

(72) Inventors: Zheng Lv, Hangzhou (CN); Chuan Peng, Hangzhou (CN); Xunyi Song, Hangzhou (CN)

(21) Appl. No.: 19/032,242

(22) Filed: Jan. 20, 2025

(30) Foreign Application Priority Data
Feb. 5, 2024 (CN) 202410166768.X

(51) Int. Cl. H10D 1/47; H10D 1/00

(52) U.S. Cl. CPC H10D 1/474; H10D 1/021

(57) ABSTRACT

A thin film resistor structure can include: an n^{th} metal layer, having a first part and a second part spaced apart from each other, and being located on an (n−1)^{th} interlayer dielectric layer; an n^{th} interlayer dielectric layer, having an upper part and a lower part, where the lower part of the n^{th} interlayer dielectric layer covers the upper surface of the n^{th} metal layer and the (n−1)^{th}interlayer dielectric layer, and where the lower part of the n^{th} interlayer dielectric layer comprises a trench exposing at least a part of the upper surface of the first and second parts of the n^{th} metal layer; and a thin film resistor, having a continuous structure located on the sidewalls and bottom of the trench, where an upper part of the n^{th} interlayer dielectric layer covers the thin film resistor and lower part of the n^{th} interlayer dielectric layer.

### RELATED APPLICATIONS

This application claims the benefit of Chinese Patent Application No. 202410166768.X, filed on Feb. 5, 2024, which is incorporated herein by reference in its entirety.

### FIELD OF THE INVENTION

The present invention generally relates to the field of semiconductors, and more particularly to thin film resistor structures and associated manufacturing methods.

### BACKGROUND

Resistors are widely used in analog circuits and their basic circuit modules, such as bandwidth voltage references, proportional operational amplifiers, and so on. In analog integrated circuits, integrated resistors are generally polysilicon resistors or active region silicon resistors. However, in some high-precision analog integrated circuits, such as multi-bit digital-to-analog converters, ordinary integrated resistors may not meet the requirements, while thin film resistors with low mismatch, low resistance temperature coefficient, and low resistance voltage coefficient can meet the requirements.

### BRIEF DESCRIPTION OF THE DRAWINGS

FIG. 1 is a cross-sectional structural diagram of an example thin film resistor.

FIG. 2 is a cross-sectional structural diagram of an example thin film resistor structure, in accordance with embodiments of the present invention.

FIGS. 3A-3G are cross-sectional structural views of certain steps of an example method of forming a thin film resistor structure, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

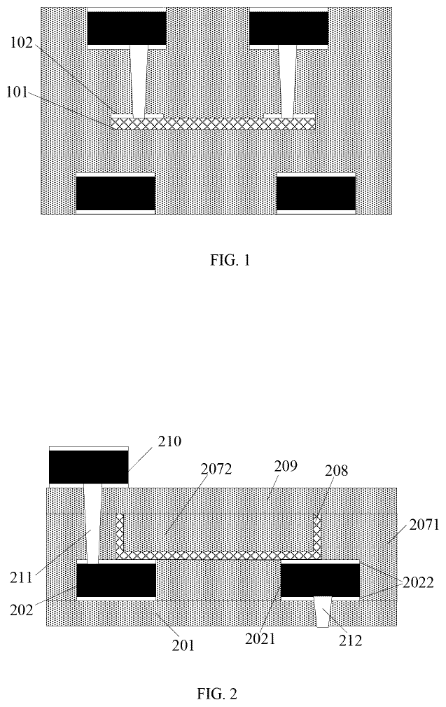

Referring now to FIG. 1, shown is a cross-sectional structural diagram of an example thin film resistor. In the manufacturing process, both thin film resistor 101 and welding layer 102 on the thin film resistor may need an etching process, that is, at least two exposure and etching steps, which can increase process costs.

Referring now to FIG. 2, shown is a cross-sectional structural diagram of an example thin film resistor structure, in accordance with embodiments of the present invention. In this particular example, the thin film resistor structure can include n^{th} metal layer 202, an n^{th} interlayer dielectric layer, thin film resistor 208, and (n+1)^{th} metal layer 210. As used herein, “n” is a positive integer, and it is understood that multiple “n” layers can be included in particular embodiments.

For example, n^{th} metal layer 202 can include a first part and a second part spaced apart from each other, and located on (n−1)^{th} interlayer dielectric layer 201. The n^{th} interlayer dielectric layer can include an upper part and lower part 2071. Lower part 2071 of the n^{th} interlayer dielectric layer can cover the upper surface of n^{th} metal layer 202 and (n−1)^{th} interlayer dielectric layer 201. Lower part 2071 of the n^{th} interlayer dielectric layer can also include a trench at least exposing portions of upper surfaces of the first part and the second part of the n^{th} metal layer.

Thin film resistor 208 can include a continuous structure located on the side walls and bottom surface of the trench, and that is in contact with upper surfaces of the first part and the second part of n^{th} metal layer 202. Upper parts 2072 and 209 of the n^{th} layer interlayer dielectric layer can cover thin film resistor 208, and (n+1)^{th} metal layer 210 may be located on the n^{th} layer interlayer dielectric layer. The (n+1)^{th} metal layer 210 can connect to the first part of the n^{th} metal layer 202 through conductive via 211, and the second part of the n^{th} metal layer 202 can connect to the (n−1)^{th} metal layer through conductive via 212, such that the thin film resistor 208 is connected between (n+1)^{th} metal layer 210 and the (n−1)^{th} metal layer.

For example, the (n+1)^{th} metal layer can connect to the first part of the n^{th} metal layer through conductive via 211 passing through the n^{th} interlayer dielectric layer, and the (n−1)^{th} metal layer can connect to the second part of the n^{th} metal layer through conductive via 212 passing through the (n−1)^{th} interlayer dielectric layer. In this particular example, the n^{th} interlayer dielectric layer can be a single oxide layer. The n^{th} metal layer 202 can include aluminum metal layer 2021, and n^{th} metal layer 202 can include aluminum metal layer 2021 and welding layers 2022 located on the upper and lower surfaces of aluminum metal layer 2021. For example, the welding layers 2022 can each be a Ti/TiN layer.

For example, a thickness of thin film resistor 208 can be greater than or equal to 20 Angstroms and less than or equal to 2000 Angstroms. For example, a height of the trench can be greater than the thickness of the thin film resistor. For example, the thickness range of the interlayer dielectric layer between the top of the thin film resistor and the lower surface of the (n+1)^{th} metal layer can be greater than or equal to 3000 Angstroms and less than or equal to 10000 Angstroms. The interlayer dielectric layer can be used to isolate the thin film resistor. For example, the material of the thin film resistor can be SiCr or SiCCr or TaN or NiCr or AlNiCr or TiNiC, or any other suitable thin film resistor materials. Through the process setting, the thin film resistor may have a temperature coefficient of resistance close to 0 ppm/° C. The shape of the thin film resistor can, e.g., be as shown in the diagrams, or can be other shapes as long as it is in contact with the n^{th} metal layer and connected between the (n+1)^{th} metal layer and the (n−1)^{th} metal layer.

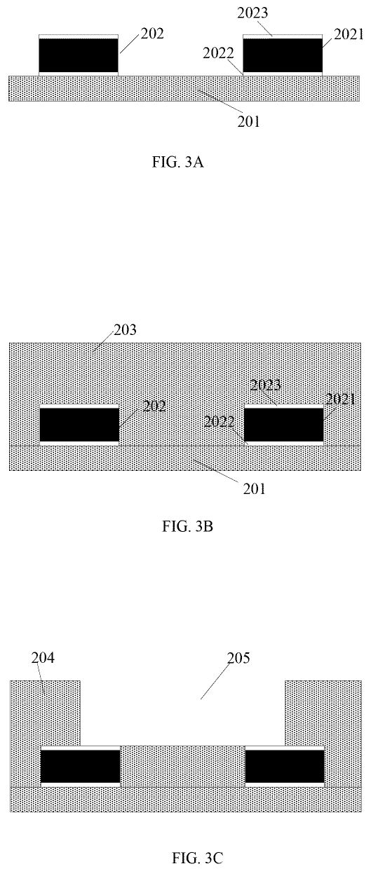

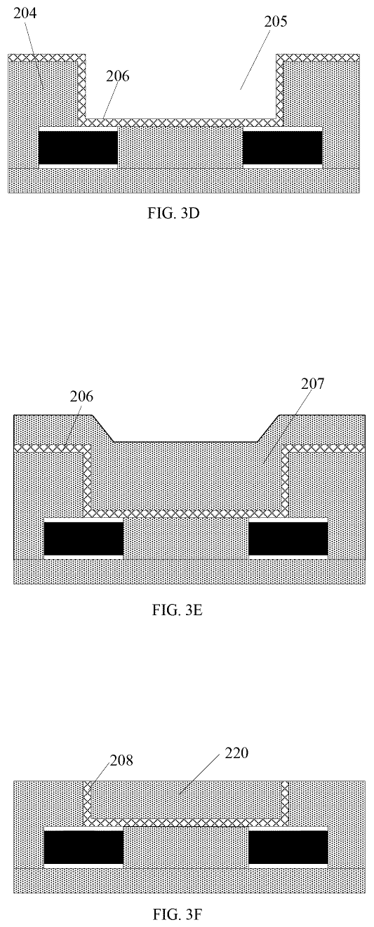

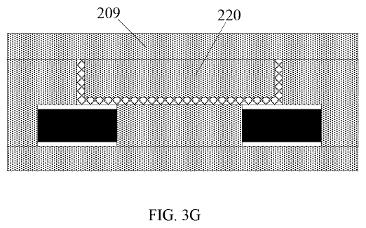

Referring now to FIGS. 3A-3G, shown are cross-sectional structural views of certain steps of an example method of forming a thin film resistor structure, in accordance with embodiments of the present invention. Particular embodiments may provide a method for forming a thin film resistor, and can include forming an n^{th} metal layer, including first and second parts spaced apart from each other, and being located on an (n−1)^{th} interlayer dielectric layer.

As shown in FIG. 3A, n^{th} metal layer 202 can be formed on (n−1)^{th} interlayer dielectric layer 201, and n^{th} metal layer 202 can include first and second parts spaced apart from each other. For example, n^{th} metal layer 202 can include aluminum metal layer 2021 and welding layers 2022 and 2023 respectively located on the lower and upper surfaces of aluminum metal layer 2021. For example, welding layers 2022 and 2023 can each be a Ti/TiN layer. It should be noted that the n^{th} metal layer can be any metal layer except the top metal layer in the semiconductor integrated circuit or device manufacturing process.

The lower part of the n^{th} interlayer dielectric layer can be formed covering the upper surface of the n^{th} metal layer and the (n−1)^{th} interlayer dielectric layer. The lower part of the n^{th} interlayer dielectric layer can include a trench that extends from the upper surface of the lower part of the n^{th} interlayer dielectric layer to an upper surface of the first and second parts of the n^{th} metal layer, and at least partially exposes the upper surface of the first and second parts of the n^{th} metal layer.

As shown in FIG. 3B, a dielectric layer can be formed on the upper surface of (n−1)^{th} interlayer dielectric layer 201 and the upper surface of n^{th} metal layer 202. For example, the dielectric layer may be formed by combining a high-density plasma deposition of multiple oxide layers (e.g., mainly filling the space between the first part and the second part of the n^{th} metal layers) and a plasma-enhanced chemical vapor deposition (PECVD) process. Then, the dielectric layer can be planarized by a chemical mechanical polishing (CMP) process, in order to form dielectric layer 203. For example, dielectric layer 203 can be a single oxide layer, and the thickness range of dielectric layer 203 can, e.g., be 4000-6000 Angstroms.

As shown in FIG. 3C, a part of dielectric layer 203 can be etched to form trench 205, which may extend from the upper surface of dielectric layer 203 to the interior of the dielectric layer until the upper surface of the n^{th} metal layer. For example, the part of upper surface of the dielectric layer coated with photoresist can be exposed through a mask, and after development, the dielectric layer may be etched by a reactive ion etching process, in order to form a lower part 204 of the n^{th} interlayer dielectric layer including trench 205. The etching process can be realized by controlling the etching time to end the etching process when it just touches the upper surface of the n^{th} metal layer. The thin film resistor can be formed as a continuous structure located in the sidewalls and bottom surface of the trench.

As shown in FIG. 3D, thin layer material 206 can be deposited on the inner surface (inner bottom and side walls) of trench 205 and the upper surface of lower part 204 of the n^{th} interlayer dielectric layer. In this particular example, thin layer material 206 can be formed by a single atomic layer deposition process, a physical vapor deposition, or a sputtering process. For example, the thickness of thin layer material 206 can be greater than or equal to 20 Angstroms and less than or equal to 2000 Angstroms. For example, thin layer material 206 can include one or more combinations of SiCr, SiCCr, TaN, NiCr, AlNiCr, TiNiC, or any other suitable thin film resistive material. The method may also include performing an annealing process on thin layer material 206. For example, the annealing temperature of the annealing process can be in the range of 400° C.-600° C. or 450° C.-550° C. (e.g., 500° C.), and the annealing time of the annealing process can be in a range of 9-11 minutes (e.g., 10 minutes), in order to obtain a thin film resistor with a temperature coefficient of resistance close to 0 ppm/° C.

As shown in FIG. 3E, interlayer dielectric layer 207 can be deposited on the upper surface of the thin layer material 206, and the thickness of interlayer dielectric layer 207 may be greater than the depth of the trench. In this particular example, interlayer dielectric layer 207 can be formed by combining a high-density plasma deposition of a multilayer oxide layer (e.g., mainly filling the trench) and a plasma-enhanced chemical vapor deposition (PECVD) process, and the thickness of interlayer dielectric layer 207 can, e.g., be in a range of 8000-12000 Angstroms.

As shown in FIG. 3F, interlayer dielectric layer 207 of the structure in FIG. 3E can be planarized by a chemical mechanical polishing (CMP) process. The planarization process can begin from the upper surface of interlayer dielectric layer 207 until the thin layer material on the upper surface of lower part 204 of the n^{th} interlayer dielectric layer is removed, and the first interlayer dielectric layer located in the trench retained. For example, the thickness of the first interlayer dielectric layer 220 that is retained can be in a range of 2000-4000 Angstroms. The thin layer material retained on the inner surface of the trench can be thin film resistor 208. In addition, the upper part of the n^{th} interlayer dielectric layer may be formed to cover the thin film resistor 208.

As shown in FIG. 3G, interlayer dielectric layer 209 can be deposited on the upper surface of the structure shown in FIG. 3F by a PECVD process to isolate thin film resistor 208. The upper part of the n^{th} interlayer dielectric layer can include a retained interlayer dielectric layer 220 and interlayer dielectric layer 209. For example, the thickness of interlayer dielectric layer 209 can be in a range of 3000-10000 Angstroms.

In addition, the example method can also include forming an (n+1)^{th} metal layer located on the n^{th} dielectric layer, and forming a first conductive via connecting the (n+1)^{th} metal layer and the first part of the n^{th} metal layer. Also, a second conductive via can be formed connecting the second part of the n^{th} layer metal layer and the (n−1)^{th} metal layer, such that the thin film resistor can connect between the (n+1)^{th} metal layer and the (n−1)^{th} metal layer.

As shown in FIG. 2, (n+1)^{th} metal layer 210 can be formed on the n^{th} interlayer dielectric layer, and the structure of the (n+1)^{th} metal layer can be the same as that of the n^{th} metal layer. Before forming the n^{th} metal layer, conductive via 212 connecting the second part of the n^{th} metal layer with the (n−1)^{th} metal layer may be formed. For example, conductive via 212 can penetrate the (n−1)^{th} layer dielectric layer to connect the second part of the n^{th} metal layer with the (n−1)^{th} metal layer. Before forming the (n+1)^{th} metal layer, conductive via 211 connecting the (n+1)^{th} metal layer 210 with the first part of the n^{th} metal layer may be formed. For example, conductive via 211 can penetrate the n^{th} dielectric layer to connect the (n+1)^{th} metal layer 210 with the first part of the n^{th} layer metal layer, such that the thin film resistor can connect in series between the (n+1)^{th} metal layer and the (n−1)^{th} metal layer.

In particular embodiments, a thin film resistor may be formed with characteristics of low mismatch, low temperature coefficient of resistance, and low voltage coefficient by using only one exposure and etching step, with a relatively simple process and low associated costs.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A thin film resistor structure, comprising:
a) an n^{th} metal layer, comprising a first part and a second part spaced apart from each other, and being located on an (n−1)^{th} interlayer dielectric layer;
b) an n^{th} interlayer dielectric layer, comprising an upper part and a lower part, wherein the lower part of the n^{th} interlayer dielectric layer covers the upper surface of the n^{th} metal layer and the (n−1)^{th} interlayer dielectric layer, and wherein the lower part of the n^{th} interlayer dielectric layer comprises a trench exposing at least a part of the upper surface of the first and second parts of the n^{th} metal layer;
c) a thin film resistor, comprising a continuous structure located on the sidewalls and bottom of the trench, wherein an upper part of the n^{th} interlayer dielectric layer covers the thin film resistor and lower part of the n^{th} interlayer dielectric layer;
d) an (n+1)^{th} metal layer, located on the n^{th} interlayer dielectric layer; and
e) wherein the thin film resistor is connected between the (n+1)^{th} metal layer and an (n−1)^{th} metal layer, and wherein the (n−1)^{th} metal layer is located below the (n−1)^{th} interlayer dielectric layer.

2. The thin film resistor structure of claim 1, wherein the (n+1)^{th} metal layer is connected to the first part of the n^{th} metal layer through a first conductive via passing through the n^{th} interlayer dielectric layer, and the (n−1)^{th} metal layer is connected to the second part of the n^{th} metal layer through a second conductive via passing through the (n−1)^{th} interlayer dielectric layer.

3. The thin film resistor structure of claim 1, wherein the n^{th} metal layer comprises an aluminum metal layer.

4. The thin film resistor structure of claim 3, wherein the n^{th} metal layer further comprises welding layers located on the upper and lower surfaces of the aluminum metal layer.

5. The thin film resistor structure of claim 1, wherein the n^{th} interlayer dielectric layer comprises a single oxide layer.

6. The thin film resistor structure of claim 1, wherein a thickness of the thin film resistor is greater than or equal to 20 Angstroms, and less than or equal to 2000 Angstroms.

7. The thin film resistor structure of claim 1, wherein a height of the trench is greater than a thickness of the thin film resistor.

8. The thin film resistor structure of claim 1, wherein a thickness of the interlayer dielectric layer between a top of the thin film resistor and a lower surface of the (n+1)^{th} metal layer is greater than or equal to 3000 Angstroms, and less than or equal to 10000 Angstroms.

9. The thin film resistor structure of claim 1, wherein the thin film resistor comprises one of: SiCr, SiCCr, TaN, NiCr, AlNiCr, and TiNiC.

10. A method of manufacturing a thin film resistor structure, the method comprising:
a) forming an n^{th} metal layer, comprising a first part and a second part spaced apart from each other, located on the (n−1)^{th} interlayer dielectric layer;
b) forming a lower part of a n^{th} interlayer dielectric layer that covers the upper surface of the n^{th} metal layer and the (n−1)^{th} interlayer dielectric layer, wherein the lower part of the n^{th} interlayer dielectric layer comprises a trench that exposes at least a part of the upper surface of the first and second parts of the n^{th} metal layer;
c) forming a thin film resistor, comprising a continuous structure located on the sidewalls and bottom surface of the trench;
d) forming an upper part of the n^{th} interlayer dielectric layer that covers the thin film resistor and the lower part of the n^{th} interlayer dielectric layer;
e) forming a (n+1)^{th} metal layer, located on the n^{th} interlayer dielectric layer; and
f) forming a first conductive via connecting the (n+1)^{th} metal layer and the first part of the n^{th} metal layer, and forming a second conductive via connecting the second part of the n^{th} metal layer and the (n−1)^{th} metal layer, such that the thin film resistor is connected between the (n+1)^{th} metal layer and the (n−1)^{th} metal layer.

11. The method of claim 10, wherein the forming a thin film resistor comprises:
a) depositing a thin layer material on the inner surface of the trench and the upper surface of the lower part of the n^{th} interlayer dielectric layer;
b) depositing a first interlayer dielectric layer on an upper surface of the thin layer material;
c) planarizing the first interlayer dielectric layer until the thin layer material on the upper surface of the lower part of the n^{th} interlayer dielectric layer being removed; and
d) wherein the thin layer material retained on the inner surface of the trench is configured as the thin film resistor, and the upper part of the n^{th} interlayer dielectric layer comprises the retained first interlayer dielectric layer.

12. The method of claim 11, further comprising forming a second interlayer dielectric layer on the retained first interlayer dielectric layer and the thin film resistor, wherein the upper part of the n^{th} interlayer dielectric layer comprises the retained first interlayer dielectric layer and the second interlayer dielectric layer.

13. The method of claim 12, wherein a thickness of the second interlayer dielectric layer is greater than or equal to 3000 Angstroms, and less than or equal to 10000 Angstroms.

14. The method of claim 10, wherein the n^{th} interlayer dielectric layer is formed by a multilayer oxide layer high-density plasma deposition and a plasma-enhanced chemical vapor deposition process.

15. The method of claim 10, wherein the forming the lower part of the n^{th} interlayer dielectric layer comprises:
a) depositing a dielectric layer to cover the upper surface of the n^{th} metal layer and the upper surface of the (n−1)^{th} interlayer dielectric layer; and
b) etching a part of the dielectric layer to form the trench, the trench extending from the upper surface of the dielectric layer to the upper surface of the n^{th} metal layer.

16. The method of claim 11, further comprising, after depositing a layer of thin layer material, performing an annealing process on the thin layer material.

17. The method of claim 10, wherein the n^{th} metal layer comprises an aluminum metal layer.

18. The method of claim 17, wherein the n^{th} metal layer further comprises welding layers located on an upper surface and a lower surface of the aluminum metal layer.

19. The method of claim 10, wherein the n^{th} interlayer dielectric layer comprises a single oxide layer.

20. The method of claim 10, wherein the first conductive via passes through the n^{th} interlayer dielectric layer, and the second conductive via passes through the (n−1)^{th} interlayer dielectric layer.
